(19) United States
(12) Patent Application Publication
(10) Pub. No.: US 2026/0319726 A1
(43) Pub. Date: Oct. 15, 2026

(54) SPLICING DISPLAY ASSEMBLY AND ELECTRONIC APPARATUS

(71) Applicants: BEIJING BOE DISPLAY TECHNOLOGY CO., LTD., Beijing (CN); BOE TECHNOLOGY GROUP CO., LTD., Beijing (CN); BEIJING BOE TECHNOLOGY DEVELOPMENT CO., LTD., Beijing (CN)

(72) Inventors: Junning SU, Beijing (CN); Wei YUAN, Beijing (CN); Zhiming MENG, Beijing (CN); He CHAO, Beijing (CN); Jianzi HE, Beijing (CN); Minghan LI, Beijing (CN); Yaolong LI, Beijing (CN); Jianyang LIU, Beijing (CN); Hanzhang NIU, Beijing (CN); Xinyu ZHANG, Beijing (CN); Yucheng ZHAO, Beijing (CN); Yu ZHANG, Beijing (CN); Jialing LV, Beijing (CN); Shou LI, Beijing (CN)

(21) Appl. No.: 18/862,117

(22) PCT Filed: Dec. 25, 2023
(86) PCT No.: PCT/CN2023/141353

§ 371 Date: Oct. 31, 2024

(51) Int. Cl. G06F 3/14; G09G 5/00

(52) U.S. Cl. CPC G06F 3/1446; G09G 5/003; G09G 2300/026; G09G 2360/04

(57) ABSTRACT

A splicing display assembly and an electronic apparatus are provided. The splicing display module includes: display modules spliced together, each including a splicing side and a back plate, a display panel, a cover plate and a first fixing member. The display panel and the cover plate are arranged on the back plate along a direction away from the back plate. For each display module, the first fixing member is located on the splicing side of the display module and is arranged on a side of the cover plate close to the back plate, and the first fixing member includes one end fixed to the cover plate and the other end fixed to the back plate. For any two display modules spliced with each other, the cover plates of the two display modules are in contact with each other at the edge of the splicing side.

### TECHNICAL FIELD

The present disclosure relates to the field of display technology, and in particular to a splicing display assembly and an electronic apparatus.

### BACKGROUND

An existing electronic blackboard of a splicing display product forms a large electronic blackboard by splicing a plurality of display screens together. The electronic blackboard cannot have a one-piece structure, so that a seam between two adjacent display screens is large, and it is difficult to align the display screens in a horizontal direction and a vertical direction.

### SUMMARY

The present disclosure is directed to at least one of the technical problems in the prior art, and provides a splicing display assembly and an electronic apparatus. In the splicing display assembly of the present disclosure, a plurality of display modules can be spliced together well, which can reduce a seam between two adjacent display modules on a splicing side at which the display modules are spliced together, and can ensure that the plurality of display modules can all be located on a same plane in a horizontal direction or a vertical direction.

In one aspect of an embodiment of the present disclosure, a splicing display module is provided to include: a plurality of display modules spliced together, wherein each display module includes a splicing side at which the display module to be spliced, each display module includes a back plate, a display panel, a cover plate and a first fixing member, and the display panel and the cover plate are arranged on the back plate along a direction away from the back plate; wherein for each display module, the first fixing member is located on the splicing side of the display module and is arranged on a side of the cover plate close to the back plate, one end of the first fixing member is fixed to the cover plate, and the other end of the first fixing member is fixed to the back plate; and for any two display modules spliced with each other, the cover plates of the two display modules are in contact with each other at an edge of the splicing side.

In some embodiments, the first fixing member includes a first fixing component and a second fixing component, the first fixing component includes a first connecting portion, a second connecting portion, and a third connecting portion connecting the first connecting portion and the second connecting portion, and the second fixing component is located on a side of the third connecting portion away from the display panel; the first connecting portion is fixedly connected to the cover plate; the third connecting portion is fixedly connected to the second fixing component, and the second connecting portion is located between the back plate and the second fixing component, and the second connecting portion, the back plate and the second fixing component are fixedly connected together.

In some embodiments, the first connecting portion is fixedly connected to the cover plate through an adhesive layer; the second connecting portion, the back plate and the second fixing component are fixedly connected together through a first fastener; and the third connecting portion is fixedly connected to the second fixing component through a second fastener.

In some embodiments, each display module further includes a non-splicing side and includes a second fixing member on the non-splicing side, and the second fixing member includes a third fixing component and a fourth fixing component; wherein the third fixing component includes a first fixing structure and a second fixing structure connected to each other, the first fixing structure is located on a side of the cover plate close to the back plate, one end of the first fixing structure is fixed to the cover plate, the other end of the first fixing structure is fixed to the back plate, the second fixing structure protrudes from the cover plate and includes a first receiving groove open to a display region, each display module further includes a first light bar in the first receiving groove, and a light emitting element of the first light bar protrudes from the cover plate; and the fourth fixing component includes a fourth connecting portion, a fifth connecting portion, and a sixth connecting portion connecting the fourth connecting portion and the fifth connecting portion, the third fixing component is located on a side of the sixth connecting portion away from the display panel, the fourth connecting portion is fixedly connected to the cover plate, the sixth connecting portion is fixedly connected to the third fixing component, the fifth connecting portion is located between the back plate and the first fixing structure of the third fixing component, and the fifth connecting portion, the back plate and the first fixing structure are fixedly connected together.

In some embodiments, the first fixing structure and the second fixing structure have a one-piece structure.

In some embodiments, the light emitting element includes a luminescent region; and in any two adjacent display modules, orthographic projections of two adjacent first fixing members on a first plane do not overlap with orthographic projections of two luminescent regions of two adjacent light emitting elements on the first plane, and the first plane is a plane where the back plate is located.

In some embodiments, a distance between two adjacent first light bars in any two adjacent display modules is less than 16 mm.

In some embodiments, each display module further includes a first filter bar fixed at an opening of the first receiving groove; and in any two adjacent display modules, an orthographic projection of a seam between two adjacent first filter bars on the first plane does not overlap with the orthographic projections of the luminescent regions of the two adjacent light emitting elements on the first plane.

In some embodiments, the light emitting element is an infrared light emitting element.

In some embodiments, each display module includes a control chip; one of the plurality of display modules is a first display module, the others are second display modules, the control chip in the first display module is a first control chip, the control chip in each second display module is a second control chip, and each second control chip is communicatively connected to the first control chip; and a driving circuit board of the first light bar in the first display module is connected to the first control chip, and a driving circuit board of the first light bar in each of the second display modules is connected to the driving circuit board of the first light bar in the first display module.

In some embodiments, the splicing display assembly includes: the first display module and the second display module on opposite sides of the first display module, wherein a size of each second display module is less than or equal to that of the first display module.

In some embodiments, the first display module further includes a first power line, each second display module includes a second power line, and each second power line is electrically connected to the first power line connected to an external power module.

In some embodiments, one of any two adjacent display modules includes a first latch fixed on the splicing side on the back plate of the display module, the other one of the two adjacent display modules includes a first positioning block corresponding to the first latch fixed on the splicing side on the back plate of the display module, and the first latch is detachably connected to the first positioning block.

In some embodiments, the first latch includes a second positioning block and a connecting rod, wherein the second positioning block is fixed on the back plate and is arranged corresponding to the first positioning block, the connecting rod has an open-loop structure, and includes a first end and a second end, which are rotatably connected to the second positioning block, and the connecting rod is capable of rotating to a side where the first positioning block is located and is fixedly connected to the first positioning block.

In some embodiments, the first latch includes a second positioning block, a handle and a connecting rod, wherein the second positioning block is fixed on the back plate and is arranged corresponding to the first positioning block, one end of the handle close to the first positioning block is rotatably connected to the second positioning block, the connecting rod has an open-loop structure, and includes a first end and a second end, which are rotatably connected to the handle, and the connecting rod is capable of rotating to a side where the first positioning block is located and is fixedly connected to the first positioning block.

In some embodiments, the first latch further includes a rotating shaft, and the first end and the second end of the connecting rod are rotatably connected to the handle by the rotating shaft penetrating through the handle.

In some embodiments, the first latch further includes a third fastener, a fourth fastener, a fifth fastener, and a sixth fastener, and the rotating shaft includes a first end and a second end; wherein the first end of the connecting rod passes through the first end of the rotating shaft, and the third fastener and the fourth fastener are located on opposite sides of the first end of the rotating shaft and are connected to the first end of the connecting rod through threads; and the second end of the connecting rod passes through the second end of the rotating shaft, and the fifth fastener and the sixth fastener are located on opposite sides of the second end of the rotating shaft and are connected to the second end of the connecting rod through threads.

In some embodiments, a first groove is arranged on a side of the first positioning block away from the first latch, and the first latch is clamped in the first groove in a splicing state.

In some embodiments, the splicing display assembly further includes: a beam on a side of the back plate of each display module away from the cover plate, and the back plate is fixed on the beam.

In some embodiments, the beam is divided into a plurality of segments, and each segment of the beam is arranged corresponding to one display module.

In some embodiments, the beam includes at least one first opening therein.

In some embodiments, one of any two adjacent display modules includes a first plug fixed on the splicing side on the back plate of the display module, the other of the two adjacent display modules includes a clamping slot fixed on the splicing side on the back plate of the display module, and the first plug is fixedly connected to the clamping slot.

In another aspect of the present disclosure, an electronic apparatus is further provided, and includes the splicing display module of any one of the above embodiments.

### BRIEF DESCRIPTION OF DRAWINGS

In order to more clearly illustrate the technical solutions of the embodiments of the present disclosure or the prior art, drawings used in the description of the embodiments or the prior art will be briefly described below. Obviously, the drawings in the following description are only some embodiments of the present disclosure, and other embodiments may be obtained from the drawings by one of ordinary skill in the art without creative efforts.

FIG. 1a is a schematic diagram of a structure of a splicing display assembly according to the present disclosure;

FIG. 1b is a schematic diagram of a structure of the splicing display assembly shown in FIG. 1a without a cover plate and a display panel;

FIG. 1c is a cross-sectional view of the splicing display assembly in FIG. 1a in a splicing state;

FIG. 2 is a schematic diagram of a structure of a first fixing member of a splicing display assembly according to the present disclosure;

FIG. 3 is a schematic diagram of a structure of a second fixing member of a splicing display assembly according to the present disclosure;

FIG. 4 is a partially enlarged schematic diagram of a region M of the splicing display assembly shown in FIG. 1a;

FIG. 5 is a schematic diagram of a portion of a splicing display assembly according to the present disclosure;

FIG. 6 is a schematic diagram of a structure of a first latch and a first fixing block according to the present disclosure;

FIG. 7 is a schematic diagram of a structure of a splicing display assembly according to the present disclosure;

FIG. 8 is a schematic diagram of a portion of the splicing display assembly shown in FIG. 7;

FIG. 9 is a schematic diagram of a structure of a portion of a splicing display assembly according to the present disclosure;

FIG. 10 is a schematic diagram of a structure of a splicing display assembly according to the present disclosure;

FIGS. 11a to 11e are schematic diagrams of the splicing display assembly in a splicing state according to the present disclosure; and

FIG. 12 is a schematic diagram of a structure of a splicing display assembly according to the present disclosure.

### DETAIL DESCRIPTION OF EMBODIMENTS

To make the objects, technical solutions and advantages of the present disclosure more apparent, the embodiments of the present disclosure are further described in detail below in combination with specific embodiments and with reference to the accompanying drawings. However, it is to be understood that the disclosed embodiments are merely examples and that other embodiments may take various alternative forms. The drawings are not necessarily drawn to scale. Certain features may be exaggerated or minimized to show details of particular components. Therefore, specific structural and functional details disclosed herein are not to be interpreted as limiting, but merely as a representative basis for teaching one of ordinary skill in the art to employ the present application in various forms. As one of ordinary skill in the art will appreciate, various features illustrated and described with reference to any one of the drawings may be combined with features illustrated in one or more other drawings to produce embodiments that are not explicitly illustrated or described. The combination of features shown provides a representative embodiment for a typical application. However, various combinations and modifications of the features consistent with the teachings of the present disclosure may be desired for certain specific applications or implementations.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly. The term “and/or”, when used to list two or more items, means that any one of the listed items or any combination of two or more of the listed items may be employed.

In an electronic blackboard, which is a splicing display product, a large electronic blackboard is formed by splicing a plurality of display modules together. The plurality of display modules may display the same or different contents, but there is no interaction among the plurality of display modules and an integrated design is not used for the plurality of display modules, so that it cannot be ensured that the plurality of display modules are in a same horizontal or vertical plane and a splicing seam between two adjacent electronic blackboards is large.

In order to solve at least one of above technical problems, in a first aspect of the embodiment of the present disclosure, a splicing display assembly is provided to include: a plurality of display modules spliced together, each display module includes a splicing side, and each display module includes a back plate, a display panel, a cover plate and a first fixing member. The display panel and the cover plate are arranged on the back plate along a direction away from the back plate. For each display module, the first fixing member is located on the splicing side of the display module and is arranged on a side of the cover plate close to the back plate, one end of the first fixing member is fixed to the cover plate, and the other end of the first fixing member is fixed to the back plate. For any two display modules spliced together, the cover plates of the two display modules are in contact with each other at the edge of the splicing side. In the splicing display assembly of the present disclosure, the display modules can be well spliced together, thereby reducing a splicing seam between every two adjacent display modules on the splicing side.

The display module of the embodiments of the present disclosure may be applied to an electronic blackboard, and a plurality of display modules are spliced together to form a large electronic blackboard.

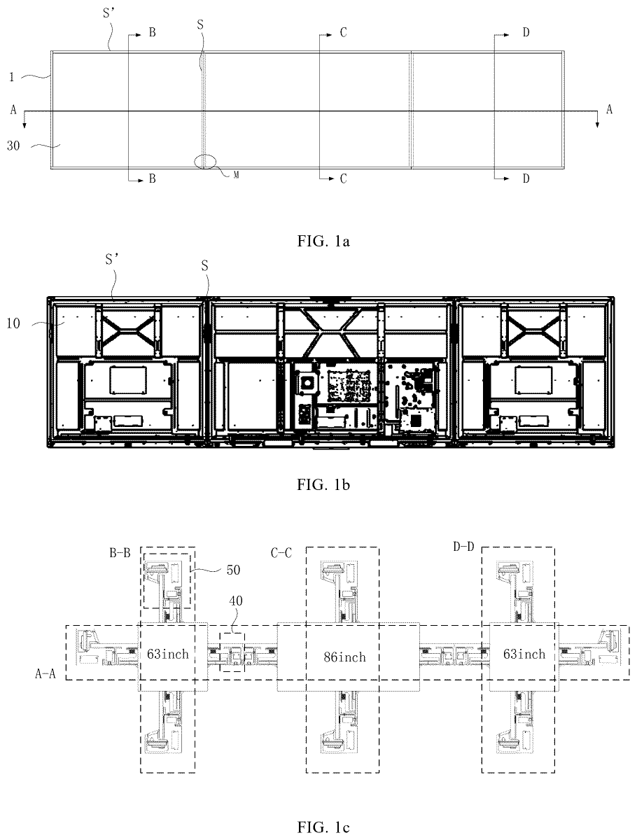

FIG. 1a is a schematic diagram of a structure of a splicing display assembly according to the present disclosure; FIG. 1b is a schematic diagram of a structure of the splicing display assembly shown in FIG. 1a without a cover plate and a display panel; FIG. 1c is a cross-sectional view of the splicing display assembly in FIG. 1a in a splicing state. The cross-sectional view of the splicing display assembly shown in FIG. 1c is a cross-sectional view obtained by splicing cross-sectional views taken along directions A-A, B-B, C-C and D-D in FIG. 1a together.

In the example in FIGS. 1a to 1c, the splicing display assembly includes: a plurality of display modules 1 spliced together, each display module includes a splicing side S, and each display module 1 includes a back plate 10, a display panel 20, a cover plate 30 and a first fixing member 40. The display panel 20 (not shown in FIGS. 1a to 1c) and the cover plate 30 are arranged on the back plate 10 along a direction away from the back plate 10. For each display module 1, the first fixing member 40 is located on the splicing side S of the display module and is arranged on a side of the cover plate 30 close to the back plate 10, one end of the first fixing member 40 is fixed to the cover plate 30, and the other end of the first fixing member 40 is fixed to the back plate 10. For any two display modules 1 spliced with each other, the cover plates 30 of the two display modules 1 are in contact with each other at the edge of the splicing side S.

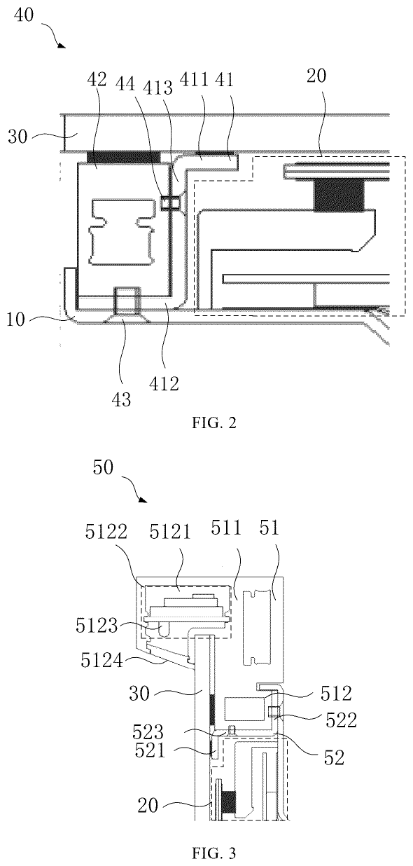

FIG. 2 is a schematic diagram of a structure of a first fixing member 40 of a splicing display assembly according to the present disclosure. In some examples, as shown in FIG. 2, the first fixing member 40 includes a first fixing component 41 and a second fixing component 42, the first fixing component 41 includes a first connecting portion 411, a second connecting portion 412, and a third connecting portion 413 connecting the first connecting portion 411 and the second connecting portion 412, the second fixing component 42 is located on a side of the third connecting portion 413 away from the display panel 20, the first connecting portion 411 is fixedly connected to the cover plate 30, the third connecting portion 413 is fixedly connected to the second fixing component 42, and the second connecting portion 412 is located between the back plate 10 and the second fixing component 42, and the second connecting portion 412, the back plate 10 and the second fixing component 42 are fixedly connected together.

There are various fixing connections between the third connecting portion 413 and the second fixing component 42, among the second connecting portion 412, the back plate 10 and the second fixing component 42, and between the first connecting portion 411 and the cover plate, which are described as examples below. It should be understood that the examples described herein are only for illustrating and explaining the present disclosure, and are not intended to limit the present disclosure.

Specifically, the first connecting portion 411 may be fixedly connected to the cover plate by an adhesive layer. The adhesive layer may be made of foam, which is not limited thereto. The adhesive layer may be made of other material having an adhesive function.

The second connecting portion 412, the back plate 10 and the second fixing component 42 are fixedly connected together by a first fastener 43. The first fastener 43 may be a screw, and the second connecting portion 412, the back plate 10 and the second fixing component 42 have threads corresponding to the screw and are fixedly connected together by the screw.

The third connecting portion 413 is fixedly connected to the second fixing component 42 by a second fastener 44. The second fastener 44 may be a screw, threads corresponding to the screw are provided at a corresponding position on the second fixing component 42, and the third connecting portion 413 is fixedly connected to the second fixing component 42 by the screw.

Through the above fixing connection, the detachable connection can be realized between the third connecting portion 413 and the second fixing component 42, among the second connecting portion 412, the back plate 10 and the second fixing component 42, and between the first connecting portion 411 and the cover plate, thereby facilitating subsequent maintenance.

FIG. 3 is a schematic diagram of a structure of a second fixing member of a splicing display assembly according to the present disclosure. In some examples, each display module 1 further includes a non-splicing side S′, as shown in FIG. 3, and includes a second fixing member 50 on the non-splicing side. The second fixing member 50 includes a third fixing component 51 and a fourth fixing component 52. The third fixing component 51 includes a first fixing structure 511 and a second fixing structure 512 connected to each other, which may have a one-piece structure. The first fixing structure 511 is located on a side of the cover plate 30 close to the back plate 10, one end of the first fixing structure is fixed to the cover plate 30 and the other end of the first fixing structure is fixed to the back plate 10. The second fixing structure 512 protrudes from the cover plate 30 and includes a first receiving groove 5121 open to a display region, a first light bar 5122 is arranged in the first receiving groove 5121, and a light emitting element 5123 of the first light bar 5122 protrudes from the cover plate 30, so that the light emitting element 5123 emits light. The fourth fixing component 52 includes a fourth connecting portion 521, a fifth connecting portion 522, and a sixth connecting portion 523 connecting the fourth connecting portion 521 and the fifth connecting portion 522, the third fixing component 51 is located on a side of the sixth connecting portion 523 away from the display panel 20, the fourth connecting portion 521 is fixedly connected to the cover plate 30, the sixth connecting portion 523 is fixedly connected to the third fixing component 51, the fifth connecting portion 522 is located between the back plate 10 and the first fixing structure 511 of the third fixing component 51, and the fifth connecting portion 522, the back plate 10 and the first fixing structure 511 are fixedly connected together. The third fixing component and the fourth fixing component can provide the support to the cover plate 30, thereby improving the reliability of the display module.

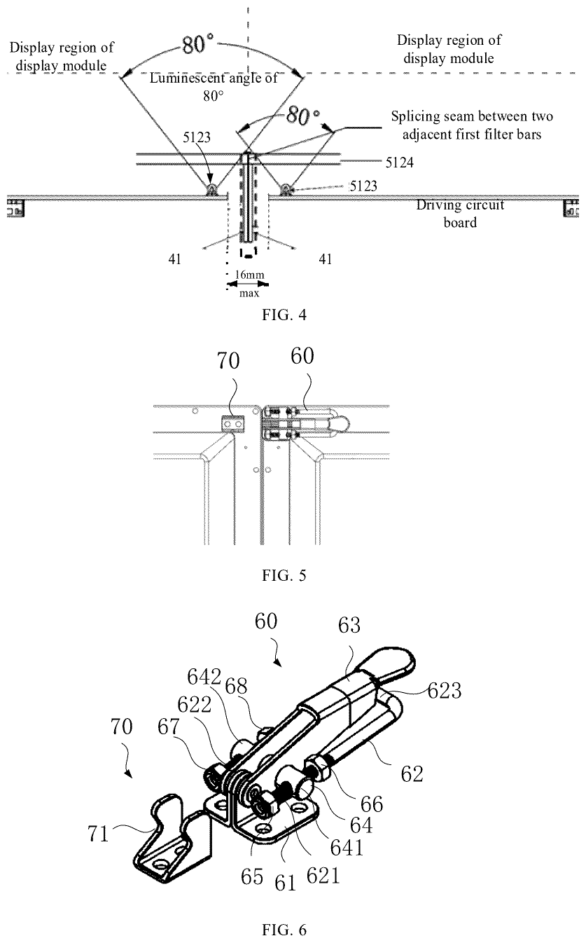

FIG. 4 is a partially enlarged schematic diagram of a region M of the splicing display assembly shown in FIG. 1a. In some examples, as shown in FIG. 4, the light emitting element 5123 includes a luminescent region. In the examples of the present disclosure, as an example, the light emitting element is an infrared light emitting element with the effective luminescent region of 80°. In any two adjacent display modules, orthographic projections of two adjacent first fixing members 40 on a first plane do not overlap with orthographic projections of two luminescent regions of two adjacent light emitting elements 5123 on the first plane. The first plane is a plane where the back plate is located. With such a configuration, the first fixing member can be prevented from blocking light emitted by the light emitting element 5123 on the splicing side, and the splicing effect can be prevented from being adversely influenced.

In some examples, in order to avoid touch failure, in any two adjacent display modules 1, a distance between two adjacent first light bars 5122 is less than 16 mm. More specifically, each first light bar 5122 includes a driving circuit board and the light emitting element 5123 arranged on the driving circuit board, and in any two adjacent display modules 1, a distance between the driving circuit boards of the two adjacent first light bars 5122 is less than 16 mm, for example, 1 mm, 2 mm, 3.5 mm, 5 mm, 6 mm, 7.8 mm, 10 mm, 12 mm, or the like. The driving circuit board may be a printed circuit board (PCB). The distance between the driving circuit boards of the first light bars 5122 of the two adjacent display modules 1 is reasonably set, so that the occurrence of an invalid touch region, that is, a region which is not covered by light emitted by the light emitting elements 5123, can be effectively avoided.

In some examples, in order to avoid touch failure, in any two adjacent display modules 1, a distance between the light emitting elements 5123 of the two adjacent first light bars 5122 is less than 20 mm, for example, 1 mm, 2 mm, 3.5 mm, 5 mm, 6 mm, 7.8 mm, 10 mm, 12 mm, 15 mm, 16 mm, 18 mm, or the like.

In some examples, as shown in FIGS. 3 and 4, a first filter bar 5124 is fixed at an opening of each first receiving groove 5121. There is a splicing seam between two adjacent first filter bars 5124 in any two adjacent display modules 1. In order to avoid the display failure of the display modules due to the overlong splicing seam, in any two adjacent display modules 1, for the splicing seam between two adjacent first filter bars 5124 and two adjacent light emitting elements 5123, the light emitted from the two light emitting elements 5123 cannot pass through the splicing seam between the first filter bars 5124.

FIG. 5 is a schematic diagram of a portion of a splicing display assembly according to the present disclosure; FIG. 6 is a schematic diagram of a structure of a first latch and a first fixing block according to the present disclosure. In some examples, as shown in FIGS. 5 and 6, for any two adjacent display modules 1, a first latch 60 is fixed on the splicing side S on the back plate 10 of one of the two adjacent display modules 1, a first positioning block 70 corresponding to the first latch 60 is fixed on the splicing side S on the back plate 10 of the other one of the two adjacent display modules 1, and the first latch 60 is detachably connected to the first positioning block 70.

In some examples, the first latch 60 includes: a second positioning block 61 and a connecting rod 62. The second positioning block 61 is fixed on the back plate 10 and is arranged corresponding to the first positioning block 70, the connecting rod 62 has an open-loop structure, and includes a first end 621 and a second end 622, which are rotatably connected to the second positioning block 61, and the connecting rod 62 may be rotated to a side where the first positioning block 70 is located and is fixedly connected to the first positioning block 70. The first positioning block 70 is provided with a first groove 71 on a side of the first positioning block 70 away from the first latch 60, and the connecting rod 62 further includes a middle portion 623 connecting the first end 621 and the second end. In the splicing state, the middle portion 623 of the connecting rod 62 of the first latch 60 is clamped in the first groove 71, so that the splicing seam between any two adjacent display modules is further reduced.

In some examples, as shown in FIGS. 5 and 6, the first latch 60 includes: the second positioning block 61, the connecting rod 62 and a handle 63. The second positioning block 61 is fixed on the back plate 10 and is arranged corresponding to the first positioning block 70, one end of the handle 63 close to the first positioning block 70 is rotatably connected to the second positioning block 61, the connecting rod 62 has an open-loop structure, and includes the first end 621, a middle portion 623, and the second end 622 connected in sequence, the first end 621 and the second end 622 are rotatably connected to the handle 63 and the handle 63 may rotate to the side where the first positioning block 70 is located and is fixedly connected to the first positioning block 70. In the splicing state, the middle portion 623 of the connecting rod 62 of the first latch 60 is clamped in the first groove 71. One end of the handle away from the first positioning block 70 is pressed down onto the back plate 10, and forms a self-locking structure with the connecting rod clamped in the first groove 71, so that the locking strength of the two adjacent display modules is improved, and the reliability of the whole splicing display assembly is improved.

In some examples, as shown in FIG. 6, the first latch 60 further includes a rotating shaft 64, and the first end 621 and the second end 622 of the connecting rod 62 are rotatably connected to the handle 63 by the rotating shaft 64 penetrating through the handle 63.

In some examples, as shown in FIG. 6, the first latch 60 further includes a third fastener 65, a fourth fastener 66, a fifth fastener 67, and a sixth fastener 68, each of which may be a nut. The rotating shaft 64 of the first latch 60 includes a first end 641 and a second end 642. The first end 621 and the second end 622 of the connecting rod 62 of the first latch 60 have threads. The first end 621 of the connecting rod 62 passes through the first end 641 of the rotating shaft 64, and the third fastener 65 and the fourth fastener 66 are located on opposite sides of the first end 641 of the rotating shaft 64 and are connected to the first end 621 of the connecting rod 62 through the threads. The second end 622 of the connecting rod 62 passes through the second end 642 of the rotating shaft 64, and the fifth fastener 67 and the sixth fastener 68 are located on opposite sides of the second end 642 of the rotating shaft 64 and are connected to the second end 622 of the connecting rod 62 through the threads.

In the splicing state, the connecting rod 62 can be prevented from moving by screwing the fifth fastener 67 and the sixth fastener 68 to the opposite sides of the second end 642 of the rotation shaft 64 and screwing the third fastener 65 and the fourth fastener 66 to the opposite sides of the first end 641 of the rotation shaft 64.

In the non-splicing state, the first end 621 of the connecting rod 62 includes a first side surface 624 facing the first positioning block 70, and the second end 622 of the connecting rod 62 includes a second side surface 625 facing the first positioning block 70. A length of the connecting rod may be adjusted by adjusting distances from the third fastener 65 and the fourth fastener 66 to the first side surface 624 of the connecting rod 62, and distances from the fifth fastener 67 and the sixth fastener 68 to the second side surface 625 of the connecting rod 62.

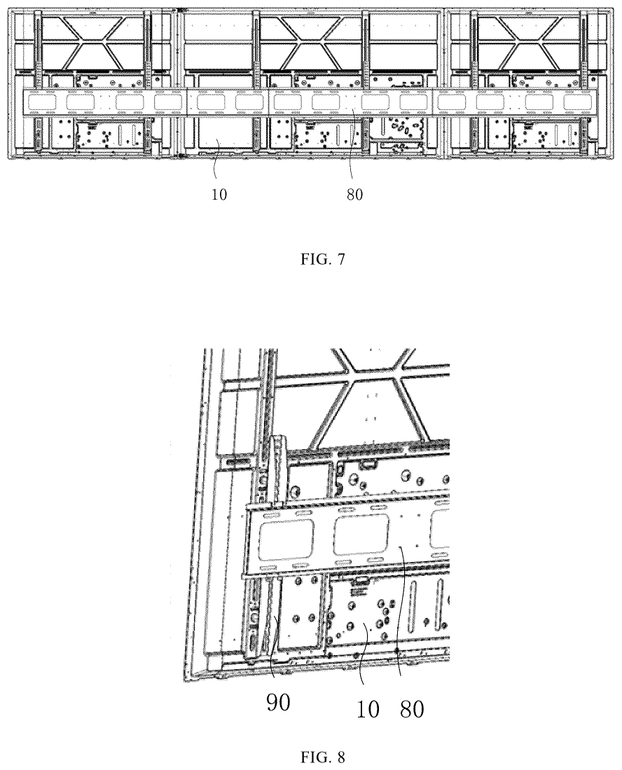

FIG. 7 is a schematic diagram of a structure of a splicing display assembly according to the present disclosure; FIG. 8 is a schematic diagram of a portion of the splicing display assembly shown in FIG. 7. In some examples, as shown in FIGS. 7 and 8, the splicing display assembly further includes: a beam 80. The beam 80 is arranged on a side of the back plate 10 of each display module 1 away from the cover plate 30, and each back plate 10 is fixed on the beam 80. It is realized through such the beam 80 that the display modules 1 are in the same plane in an extending direction of the beam 80. The beam 80 may be fixedly connected to the back plate 10 by a bracket 90.

In some examples, as shown in FIGS. 7 and 8, when the excessively long beam 80 is processed, since the beam 80 is strip-shaped and is easily deformed during processing the beam 80, the beam 80 may be divided into a plurality of segments, and each segment of the beam 80 is arranged corresponding to one display module 1.

In some examples, to increase a strength of the beam 80, at least one first opening 81 is provided in the beam 80. In the example of the present disclosure as shown in FIG. 7, a plurality of first openings 81 are provided side by side along an extending direction of the beam 80.

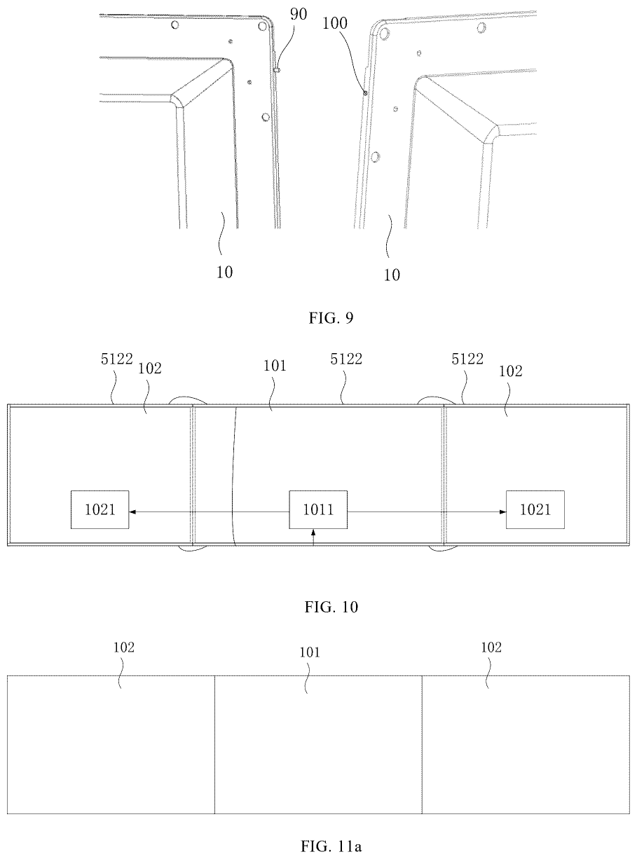

FIG. 9 is a schematic diagram of a structure of a portion of a splicing display assembly according to the present disclosure. In some examples, as shown in FIG. 9, for any two adjacent display modules 1, a first plug 90 is fixed on the back plate 10 of one of the display modules on the splicing side S, a clamping slot 100 is fixed on the back plate 10 of the other display module on the splicing side, and the first plug 90 and the clamping slot 100 may be fixedly connected with each other. Specifically, in the splicing state, the first plug 90 is inserted into the clamping slot 100, which realize the position-limiting of the two adjacent display modules 1, so that positions of the cover plates 30 and the display panels 20 of the display modules 1 in a horizontal direction and a vertical direction are kept consistent.

FIG. 10 is a schematic diagram of a structure of a splicing display assembly according to the present disclosure. In some examples, as shown in FIG. 10, each display module 1 includes a control chip.

One of the display modules 1 is a first display module 101, and the others are second display modules 102. The control chip in the first display module 101 is a first control chip 1011, and the control chip in each second display module 102 is a second control chip 1021. Each second control chip 1021 is communicatively connected to the first control chip 1011.

The driving circuit board of the first light bar 5122 in the first display module 101 is connected to the first control chip 11, and the driving circuit board of the first light bar 5122 in each of the second display modules 102 is connected to the driving circuit board of the first light bar 5122 in the first display module 101.

The first display module 101 further includes a first power line, each second display module 102 includes a second power line, and each second power line is electrically connected to the first power line connected to an external power module. The external power module may be an external power socket, an external power supply, or the like, and may be provided as a module configured to provide a voltage.

The power lines in the example of the present disclosure are provided in an integrated routing mode, which facilitates the use of the product.

In some examples, for the first display module 101 and the second display modules 102 on the opposite sides of the first display module 101, a size of each second display module 102 is less than or equal to that of the first display module 101.

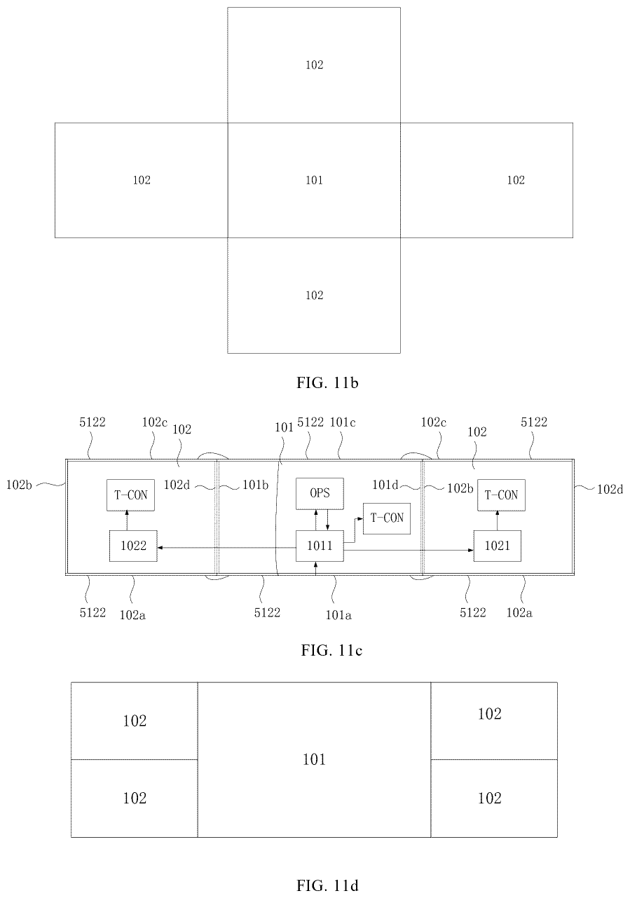

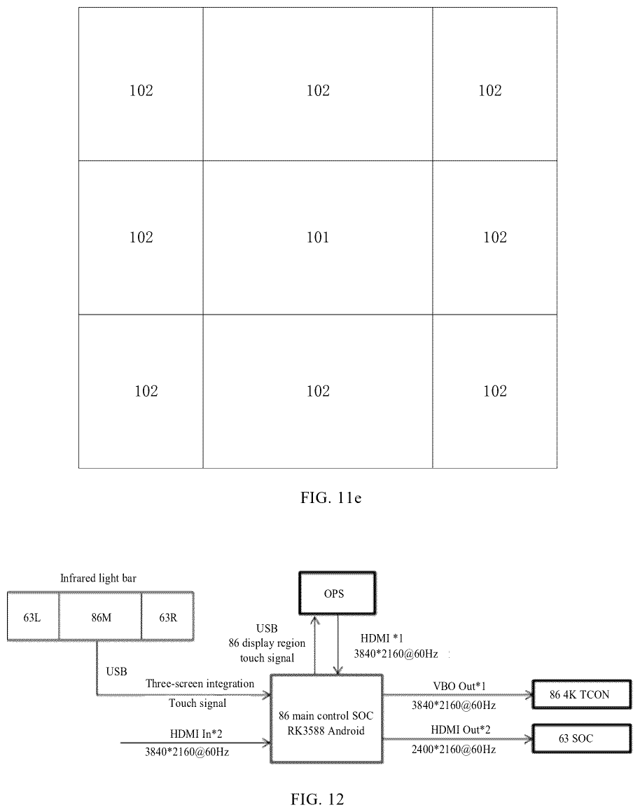

FIGS. 11a to 11e each are a schematic diagram of the splicing display assembly in a splicing state according to the present disclosure.

A splicing application scenario, a routing application scenario, and a communication process of the first display module 101 and the second display modules 102 are specifically described below with reference to FIGS. 11a to 11e.

In the splicing application scenario:

In an application scenario, as shown in FIG. 11a, the splicing display assembly includes one first display module 101 and two second display modules 102 located on the opposite sides of the first display module 101, and each of the two second display modules 102 has the same size as the first display module 101.

In an application scenario, as shown in FIG. 11b, the splicing display assembly further includes one first display module 101 and four second display modules 102 located on two pairs of opposite sides of the first display module 101, and each of the four second display modules 102 has the same size as the first display module 101.

In an application scenario, as shown in FIG. 11c, the splicing display assembly further includes one first display module 101 and two second display modules 102 located on the opposite sides of the first display module 101 and having the same size, which is less than that of the first display module 101. For example, the first display module 101 is a 86-inch display module, and each second display module 102 is a 63-inch display module.

In an application scenario, as shown in FIG. 11d, the splicing display assembly further includes one first display module 101 and four second display modules 102, two of the four second display modules 102 are spliced together and the others of the four second display modules 102 are spliced together along a width direction of the splicing display assembly, the two splicing second display modules are located on the opposite sides of the first display module 101, and the four second display modules 102 have the same size, which is less than that of the first display module 101.

In an application scenario, as shown in FIG. 11e, the splicing display assembly further includes one first display module 101 and eight second display modules 102 arranged around the first display module 101, a size of each of the second display modules 102 located on the opposite sides of the first display module 101 along a splicing height direction is equal to that of the first display module 101, and a size of each of the remaining second display modules 102 is less than that of the first display module 101.

In the routing application scenario, and the communication process:

In the routing application scenario, the splicing display assembly of the example of the present disclosure is described by taking as an example the splicing display assembly as shown in FIG. 11c. Specifically, the first display module 101 includes a first non-splicing side 101a, a first splicing side 101b, a second non-splicing side 101c, and a second splicing side 101d, the first non-splicing side and the second non-splicing side of the first display module 101 are opposite to each other, and the first splicing side 101b and the second splicing side 101d of the first display module 101 are opposite to each other.

Each second display module 102 includes a first non-splicing side 102a, a second non-splicing side 102b, a third non-splicing side 102c, and a splicing side 102d, the first non-splicing side and the third non-splicing side of the second display module 102 are opposite to each other, and the second non-splicing side 102b and the splicing side 102d of the second display module 102 are opposite to each other.

The first light bar 5122 of each of the two second display modules 102 on the first non-splicing side 102a is electrically connected to the first light bar 5122 of the first display module 101 on the first non-splicing side 101a, the first light bar of each of the two second display modules 102 on the third non-splicing side 102c is electrically connected to the first light bar 5122 of the first display module 101 on the third non-splicing side 101c, the first light bar 5122 of the first display module 101 on the first non-splicing side 101a is electrically connected to the first light bar 5122 of the first display module 101 on the third non-splicing side 101c, and the first light bar 5122 of the first display module 101 on the first non-splicing side 101a or on the third non-splicing side 101c is electrically connected to the first control chip 1011. The first control chip 1011 of the first display module 101 is electrically connected to the second control chip 1021 of each second display module 102.

In the example of the present disclosure, the first light bars 5122 of the display modules adopt a segmented routing manner, which is beneficial to the assembly of the display modules, and avoids the touch failure caused by an overlong size of the splicing display assembly in a splicing direction.

In some examples, because the overlong size of the splicing display assembly in the splicing direction causes that the light emitting elements on the first light bars on the opposite sides of the splicing display assembly in the splicing direction are difficult to aligned with each other, which causes the touch failure. In order to solve this problem, the first fixing members are provided on the opposite sides of the splicing display assembly in the splicing direction instead of the second fixing members on the opposite sides of the splicing display assembly in the splicing direction, which effectively avoids the touch failure caused by the fact that the light emitting elements on the first light bars of the third fixing components of the second fixing members on the opposite sides of the splicing display assembly in the splicing direction are difficult to align with each other.

Each first light bar 5122 may be an infrared light bar. When the splicing display assembly is in operation, infrared light is emitted from infrared light emitting elements on the infrared light bars of the display modules to form an optical network formed by infrared rays. When a user touches a point of the display panel, the infrared rays passing through the point in the horizontal direction and the vertical direction may be shielded by fingers or other opaque objects, from which coordinate information of the touch point may be analyzed through the driving circuit boards on the infrared light bars, and is sent to the control chips, which in turn generate display coordinate information according to the coordinate information of the touch point, and control the display panel to display according to the generated display coordinate information.

In some examples, as shown in FIG. 11c, the first display module 101 further includes: a timing control module (T-CON for short) and an open pluggable specification (OPS, that is, a computing module plug-in format) computer box. Each second display module 102 further includes: a timing control module. Each timing control module is used for receiving the display information sent by the control chip and controlling the display panel to display. The OPS computer box is used for enhancing the computing power of the first control chip. The routing length between the OPS computer box and the first control chip should be as short as possible, for example, the OPS computer box and the first control chip are connected to each other in a form of a straight line, so that the signal interference and the radiation are reduced.

In some examples, the signal lines among the modules of the display modules are separated from the power lines among the display modules, so that mutual interference between the signal lines and the power lines is avoided.

FIG. 12 is a schematic diagram of a structure of a splicing display assembly according to the present disclosure. In some examples, as shown in FIG. 12, the first control chip 1011 includes HDMI input ports, an HDMI output port, a USB input port, a USB output port, and a VBO (video by one) output port. The first control chip 1011 may be a system on chip (SOC).

In general, a video signal is transmitted from a PC, a set-top box, and a notebook to an SOC of a display, and is a signal transmitted between external devices, and has a signal format such as VGA (video graphics array), DVI (digital video interactive), HDMI, or the like. The conversion of the format of the video signal can be realized through the SOC, and the video signal is converted into a signal supported by a TCON (timer control register). For example, a signal in a VGA format is converted into a signal in an LVDS (low voltage differential signaling) format, and a signal in an HDMI format is converted into a signal in a VBO format. The SOC may further realize functions involving power on/off, backlight brightness, and playback volume and the like.

Specifically, as shown in FIGS. 11c and 12, the first light bar 5122 of the first display module 101 on the first non-splicing side 101a or on the third non-splicing side 101c may transmit a touch coordinate signal to the first control chip 1011 through a USB data line. The first control chip 1011 may receive an input signal from the HDMI input port from an external computer. The first control chip 1011 may transmit the display coordinate information to the corresponding second control chip 1021 through the HDMI output port. The first control chip 1011 may further transmit the display coordinate information to the timing control module via the VBO output port. The first control chip 1011 may further transmit the touch coordinate information to the OPS computer box through the USB output port, and receive the display coordinate information returned by the OPS computer box based on the touch coordinate signal through the HDMI input port. HDMI input and output may support various resolutions, such as 2400×2160, 3840×2160 and the like, and VBO output may support various resolutions, for example, 2400×2160, 3840×2160 and the like.

The splicing display assembly in the embodiment of the present disclosure supports the input of a touch signal, and realizes the mapping between the touch coordinate and the display coordinate, and supports the control and display of the OPS computer box, the output of the touch coordinate, and the HDMI input. The splicing display assembly in the embodiment of the present disclosure can realize the interaction of a plurality of display pictures of the plurality of display modules, support a multi-screen integration function to display a complete picture, support each display screen to independently display different contents, support three screens to independently display different applications, support display screens of the second display modules to synchronously display a same picture, support display pictures of the second display modules to be exchanged with each other, support many people to simultaneously write on the plurality of display modules, support to store the written content and support the wireless projection.

The display process of the splicing display assembly shown in FIG. 11c is described below. In the following example, the first light bar 5122 of the first display module 101 on the first non-splicing side 101a is electrically connected to the first control chip 1011, and the first light bar 5122 is an infrared light bar, as an example.

In a scenario 1: the infrared light bar of the first display module 101 on the first non-splicing side 101a controls a display region 1 of the first display module 101, the infrared light bar of the first display module 101 on the second non-splicing side 101c controls a display region 2 of the first display module 101, and the touch point is located in the display region 2 of the first display module 101.

The driving circuit board of the infrared light bar of the first display module 101 on the second non-splicing side 101c acquires a touch signal, analyzes touch coordinate information according to the touch signal, and transmits the touch coordinate information to the driving circuit board of the infrared light bar of the first display module 101 on the first non-splicing side 101a, which in turn transmits the touch coordinate information to the first control chip 1011, and the first control chip 1011 generates corresponding display coordinate information according to the touch coordinate information and controls the display panel 20 to display based on the display coordinate information.

In a scenario 2: the infrared light bar of each second display module 102 located on the first non-splicing side 102a controls a display region 1 of the second display module 102, the infrared light bar of each second display module 102 located on the third non-splicing side 102c controls a display region 2 of the second display module 102, and the touch point is located in the display region 1 of the second display module 102.

The driving circuit board of the infrared light bar of each second display module 102 on the first non-splicing side 102a acquires a touch signal, analyzes the touch coordinate information according to the touch signal, and transmits the touch coordinate information to the driving circuit board of the infrared light bar of the first display module 101 on the first non-splicing side 101a, which in turn transmits the touch coordinate information to the first control chip, the first control chip generates corresponding display coordinate information according to the touch coordinate information, and transmits the display coordinate information to the second control chip 1021 of the second display module 102, and the second control chip 1021 controls the display panel 20 corresponding to the second control chip 1021 to display after receiving the display coordinate information.

Based on the same inventive concept, in a second aspect of the embodiments of the present disclosure, an electronic apparatus is provided to include the splicing display assembly of any one of the above embodiments.

One of ordinary skill in the art will understand that any one of the above embodiments is only exemplarily discussed, and is not intended to imply that the protection scope disclosed in the embodiments of the present disclosure is limited to these examples. With the inventive idea of embodiments of the present disclosure, the technical features in the above embodiments or different embodiments may alternatively be combined with each other, and there are many other variations of the different aspects of the embodiments of the present disclosure as described above, which are not provided in detail for the sake of brevity. Therefore, any omissions, modifications, equivalent substitutions, improvements, and the like that may be made without departing from the spirit or scope of the embodiments of the present disclosure are intended to be included within the scope of the embodiments of the present disclosure.

1. A splicing display assembly, comprising:
a plurality of display modules spliced together, wherein each display module comprises a splicing side, each display module comprises a back plate, a display panel, a cover plate and a first fixing member, and the display panel and the cover plate are arranged on the back plate along a direction away from the back plate; wherein
for each display module, the first fixing member is located on the splicing side of the display module and is arranged on a side of the cover plate close to the back plate, one end of the first fixing member is fixed to the cover plate, and the other end of the first fixing member is fixed to the back plate; and
for any two display modules spliced with each other, the cover plates of the two display modules are in contact with each other at an edge of the splicing side.

2. The splicing display assembly of claim 1, wherein the first fixing member comprises a first fixing component and a second fixing component, the first fixing component comprises a first connecting portion, a second connecting portion, and a third connecting portion connecting the first connecting portion and the second connecting portion, and the second fixing component is located on a side of the third connecting portion away from the display panel;
the first connecting portion is fixedly connected to the cover plate;
the third connecting portion is fixedly connected to the second fixing component, and
the second connecting portion is located between the back plate and the second fixing component, and the second connecting portion, the back plate and the second fixing component are fixedly connected together.

3. The splicing display assembly of claim 2, wherein the first connecting portion is fixedly connected to the cover plate through an adhesive layer;
the second connecting portion, the back plate and the second fixing component are fixedly connected together through a first fastener; and
the third connecting portion is fixedly connected to the second fixing component through a second fastener.

4. The splicing display assembly of claim 1, wherein each display module further comprises a non-splicing side and comprises a second fixing member on the non-splicing side, and the second fixing member comprises a third fixing component and a fourth fixing component; wherein
the third fixing component comprises a first fixing structure and a second fixing structure connected to each other, the first fixing structure is located on a side of the cover plate close to the back plate, one end of the first fixing structure is fixed to the cover plate, the other end of the first fixing structure is fixed to the back plate, the second fixing structure protrudes from the cover plate and comprises a first receiving groove with an opening facing to a display region, each display module further comprises a first light bar in the first receiving groove, and a light emitting element of the first light bar protrudes from the cover plate; and
the fourth fixing component comprises a fourth connecting portion, a fifth connecting portion, and a sixth connecting portion connecting the fourth connecting portion and the fifth connecting portion, the third fixing component is located on a side of the sixth connecting portion away from the display panel, the fourth connecting portion is fixedly connected to the cover plate, the sixth connecting portion is fixedly connected to the third fixing component, the fifth connecting portion is located between the back plate and the first fixing structure of the third fixing component, and the fifth connecting portion, the back plate and the first fixing structure are fixedly connected together.

5. The splicing display assembly of claim 4, wherein the first fixing structure and the second fixing structure have a one-piece structure.

6. The splicing display assembly of claim 4, wherein the light emitting element comprises a luminescent region; and
in any two adjacent display modules, orthographic projections of two adjacent first fixing members on a first plane do not overlap with orthographic projections of two luminescent regions of two adjacent light emitting elements on the first plane, and the first plane is a plane where the back plate is located.

7. The splicing display assembly of claim 6, wherein a distance between two adjacent first light bars in any two adjacent display modules is less than 16 mm, or
each display module further comprises a first filter bar fixed at the opening of the first receiving groove; and in any two adjacent display modules, an orthographic projection of a seam between two adjacent first filter bars on the first plane does not overlap with the orthographic projections of the luminescent regions of the two adjacent light emitting elements on the first plane.

8. (canceled)

9. The splicing display assembly of claim 4, wherein the light emitting element is an infrared light emitting element.

10. The splicing display assembly of claim 4, wherein each display module comprises a control chip;
one of the plurality of display modules is a first display module, the others are second display modules, the control chip in the first display module is a first control chip, the control chip in each second display module is a second control chip, and each second control chip is communicatively connected to the first control chip; and
a driving circuit board of the first light bar in the first display module is connected to the first control chip, and a driving circuit board of the first light bar in each of the second display modules is connected to the driving circuit board of the first light bar in the first display module.

11. The splicing display assembly of claim 10, comprising: the first display module and the second display modules on opposite sides of the first display module,
wherein a size of each second display module is less than or equal to that of the first display module.

12. The splicing display assembly of claim 10, wherein the first display module further comprises a first power line, each second display module comprises a second power line, and each second power line is electrically connected to the first power line connected to an external power module.

13. The splicing display assembly of claim 1, wherein one display module of any two adjacent display modules comprises a first latch fixed on the splicing side on the back plate of the one display module, the other display module of the two adjacent display modules comprises a first positioning block, corresponding to the first latch, fixed on the splicing side on the back plate of the other display module, and the first latch is detachably connected to the first positioning block.

14. The splicing display assembly of claim 13, wherein the first latch comprises a second positioning block and a connecting rod, wherein the second positioning block is fixed on the back plate and is arranged corresponding to the first positioning block, the connecting rod has an open-loop structure, and comprises a first end and a second end, which are rotatably connected to the second positioning block, and the connecting rod is capable of rotating to a side where the first positioning block is located and is fixedly connected to the first positioning block.

15. The splicing display assembly of claim 13, wherein the first latch comprises a second positioning block, a handle and a connecting rod, wherein the second positioning block is fixed on the back plate and is arranged corresponding to the first positioning block, one end of the handle close to the first positioning block is rotatably connected to the second positioning block, the connecting rod has an open-loop structure, and comprises a first end and a second end, which are rotatably connected to the handle, and the connecting rod is capable of rotating to a side where the first positioning block is located and is fixedly connected to the first positioning block, and
the first latch further comprises a rotating shaft, and the first end and the second end of the connecting rod are rotatably connected to the handle by the rotating shaft penetrating through the handle.

16. (canceled)

17. The splicing display assembly of claim 15, wherein the first latch further comprises a third fastener, a fourth fastener, a fifth fastener, and a sixth fastener, and the rotating shaft comprises a first end and a second end; wherein
the first end of the connecting rod passes through the first end of the rotating shaft, and the third fastener and the fourth fastener are located on opposite sides of the first end of the rotating shaft, and are connected to the first end of the connecting rod through threads; and
the second end of the connecting rod passes through the second end of the rotating shaft, and the fifth fastener and the sixth fastener are located on opposite sides of the second end of the rotating shaft, and are connected to the second end of the connecting rod through threads.

18. The splicing display assembly of claim 13, further comprising a first groove on a side of the first positioning block away from the first latch, wherein the first latch is clamped in the first groove in a splicing state.

19. The splicing display assembly of claim 1, further comprising:
a beam on a side of the back plate of each display module away from the cover plate, wherein the back plate is fixed on the beam.

20. The splicing display assembly of claim 19, wherein the beam is divided into a plurality of segments, and each segment of the beam is arranged corresponding to one display module, or
the beam comprises at least one first opening therein.

21. (canceled)

22. The splicing display assembly of claim 1, wherein one display module of any two adjacent display modules comprises a first plug fixed on the splicing side on the back plate of the one display module, the other display module of the two adjacent display modules comprises a clamping slot fixed on the splicing side on the back plate of the other display module, and the first plug is fixedly connected to the clamping slot.

23. An electronic apparatus, comprising the splicing display assembly of claim 1.
